(19) United States
(12) Patent Application Publication
(10) Pub. No.: US 2008/0061425 A1
(43) Pub. Date: Mar. 13, 2008

(54) CHIP PACKAGE STRUCTURE AND FABRICATING METHOD THEREOF

(75) Inventors: Da-Shuang Kuan, Hsinchu County (TW); Tony Whitehead, Hsinchu City (TW); Tzrong-Li Han, Hsinchu Hsien (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, omitted

(73) Assignee: UNITED MICRODISPLAY OPTRONICS CORP., Hsin-Chu City (TW)

(21) Appl. No.: 11/531,688

(22) Filed: Sep. 13, 2006

(51) Int. Cl. H01L 23/48

(52) U.S. Cl. 257/693

(57) ABSTRACT

A chip package structure comprising a chip, a packaging cover panel and an adhesion layer is provided. The chip has an active surface. An image-sensing device is disposed on the active surface and a plurality of contact pads is disposed around the image-sensing device. The package cover panel is disposed over the active surface. The package cover panel includes a substrate and a supporting part disposed on the substrate such that the supporting part defines a cavity on the substrate. The supporting part may contact with the active surface of the chip so that the image-sensing device on the active surface is located within the cavity. The adhesion layer is disposed between the supporting part and the active surface.

### BACKGROUND OF THE INVENTION

1. Field of the Invention

The present invention relates to a chip package structure and fabricating method thereof. More particularly, the present invention relates to a chip package structure with a package cover panel and the fabricating method thereof.

2. Description of the Related Art

In the manufacturing semiconductors, the production of integrated circuits (IC) can be roughly divided into three major stages: the wafer fabrication stage, the integrated circuit (IC) fabrication stage and the integrated circuit packaging stage. In general, the steps for fabricating a naked die or chip includes wafer production, circuit design, mask making and wafer sawing. Furthermore, after cutting out the naked dies from a wafer, the contacts on each naked die must be electrically connected to corresponding external signaling points and then packaged by encapsulating with a molding compound. The purpose of packaging the die or chip is to prevent any moisture, heat or noise from affecting the properties and operation of the die. Furthermore, the package also provides a medium for electrically connecting the die with outside electrical devices.

In the conventional IC packaging process, after cutting the wafer to form a plurality of naked dies, a wire-bonding process or flip chip process is carried out to make electrical connections between the contacts on the naked die with external signaling points. The die is encapsulated using a molding compound only after proper wiring connections are made. Hence, before the naked die is encapsulated, external particles can easily drop onto the naked die and lower the yield of a conventional chip package structure. Moreover, the aforesaid packaging structure entails a high production cost.

To resolve the above problems, another conventional chip package structure has been developed. FIG. 1 is a schematic cross-sectional view of a conventional chip package structure. As shown in FIG. 1, the chip package structure 200 comprises a chip 210, a package cover panel 220 and a spacer 230a. The chip 210 has an active surface 212 with an image-sensing device 214 disposed thereon and a plurality of contact pads 216 disposed around the image-sensing device 214. In addition, the spacer 230a is surrounded and enclosed within an adhesion layer 230b. Hence, the package cover panel 220 is actually supported by the spacer 230a and adhered by the adhesion layer 230b to the active surface 212.

Although the packaging method can reduce the production cost and increase the yield of the packaging process, the connection between the chip 210 and the package cover panel 220 is achieved through the support and adhesion of the spacer 230a and the adhesion layer 230b. However, the optical transmissivity of the spacer 230a and the adhesion layer 230b is low so that the optical transmissivity of the chip package structure 200 as a whole is reduced.

In addition, due to the height limitation of the spacer 230a, the distance separating the package cover panel 220 and the image-sensing device 214 in the chip package structure 200 is very small. Therefore, when external micro-particles drop and attach to the outer surface of the package cover panel 220, the micro-particles may be imaged leading to a drop in the optical quality produced by the image-sensing device 214.

Accordingly, the defects of a conventional chip package structure include a low process yield, a high production cost, a low optical transmissivity and inferior optical device performance quality. Thus, there is an urgent need to develop better chip package structures.

### SUMMARY OF THE INVENTION

Accordingly, at least one objective of the present invention is to provide a package cover panel that can resolve the problem of having a low optical transmissivity in the conventional chip package structure.

At least another objective of the present invention is to provide a chip package structure that can resolve the problem of having a low process yield, a high production cost, a low optical transmissivity and an inferior device performance quality in the conventional chip package structure.

At least yet another objective of the present invention is to provide a method of fabricating a chip package structure that can resolve the problem of having a low process yield and a high production cost in the conventional chip package structure.

To achieve these and other advantages and in accordance with the purpose of the invention, as embodied and broadly described herein, the invention provides a package cover panel for packaging a wafer. The wafer comprises a plurality of device regions. The package cover panel includes a substrate and a supporting part. The supporting part is disposed on the substrate. The supporting part defines a plurality of cavities on the substrate and each cavity will correspond with a device region on the wafer.

According to one preferred embodiment of the present invention, the supporting part has a height between 15 μm to 50 μm, for example.

According to one preferred embodiment of the present invention, the top end of the supporting part has a groove, for example. In addition, the package panel cover further includes an adhesion layer disposed inside the groove.

According to one preferred embodiment of the present invention, the package panel cover further includes at least an alignment mark disposed on the substrate.

According to one preferred embodiment of the present invention, the package cover panel is fabricated using glass or polymethyl methacrylate (PMMA), for example.

The present invention also provides a chip package structure comprising a chip, a package cover panel and an adhesion layer. The chip has an active surface. An image-sensing device is disposed on the active surface and a plurality of contact pads is disposed around the image-sensing device. The package cover panel is disposed above the active surface. The package cover panel includes a substrate and a supporting part on the substrate. The supporting part defines a cavity on the substrate. The supporting part is in contact with the active surface so that the image-sensing device on the active surface is disposed inside the cavity. Furthermore, the adhesion layer is disposed between the supporting part and the active surface.

According to one preferred embodiment of the present invention, the supporting part has a height greater than the image-sensing device, for example.

According to one preferred embodiment of the present invention, the supporting part has a height between 15 μm to 50 μm, for example.

According to one preferred embodiment of the present invention, the top end of the supporting part has a groove, for example. In addition, the adhesion layer is disposed inside the groove.

According to one preferred embodiment of the present invention, the package cover panel is fabricated using glass or polymethyl methacrylate (PMMA), for example.

The present invention also provides a method of fabricating a chip package structure comprising the following steps. First, a wafer with an active surface is provided. The active surface has a plurality of image-sensing device disposed thereon and a plurality of contact pads disposed around each image-sensing device. Then, a package cover panel is provided. The package cover panel includes a substrate and a supporting part disposed on the substrate. The supporting part defines a plurality of cavities on the substrate. An adhesion layer is formed between the supporting part and the active surface of the wafer so that the package cover panel connects with the active surface of the wafer. Each image-sensing device on the wafer is disposed within a corresponding cavity. Finally, the package cover panel and the wafer are separately dissected to form a plurality of chip package structures.

According to one preferred embodiment of the present invention, the package cover panel is formed by performing photolithographic and etching processes or formed by performing an injection molding process.

According to one preferred embodiment of the present invention, the supporting part has a height greater than the image-sensing device on the wafer, for example.

According to one preferred embodiment of the present invention, the supporting part has a height between 15 μm to 50 μm, for example.

According to one preferred embodiment of the present invention, the process of forming the package cover panel further includes forming a groove at the top end of the supporting part and coating an adhesion layer within the groove, for example.

According to one preferred embodiment of the present invention, the process of forming the package cover panel further includes forming at least an alignment mark on the package cover panel. In addition, the step of connecting the package cover panel with the active surface of the wafer further includes performing an alignment using the alignment mark, for example.

According to one preferred embodiment of the present invention, the package cover panel is fabricated using glass or polymethyl methacrylate (PMMA), for example.

Since the chip package structure in the present invention is formed by directly packaging the wafer with a package cover panel before cutting out the wafer to form individual chip packages, the chance of having external micro-particles dropping and attaching to the surface of the chip is minimized. Hence, the chip package structure and the fabrication method according to the present invention can increase process yield. Moreover, the chip package structure has simpler processing steps and a lower production cost than the conventional method.

Because the supporting part of the package cover panel and the substrate inside the chip package structure according to the present invention are fabricated using a transparent material, the chip package structure has an optical transmissivity much better than a conventional chip package structure.

Furthermore, the height of the supporting part can be designed according to the required distance of separation between the chip and the package cover panel. When the height of the supporting part reaches a definite level, any micro-particles attached to the outer surface of the package cover panel will be out of focus and hence can no longer form an image. In other words, the effect of external micro-particles on the optical properties of the image-sensing device will be minimized.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic cross-sectional view of a conventional chip package structure.

FIG. 2 is a schematic cross-sectional view of a chip package structure according to one preferred embodiment of the present invention.

FIG. 3 is a top view of the chip package structure shown in FIG. 2.

FIGS. 4 to 6 are schematic cross-sectional views showing the steps for forming the chip package structure shown in FIG. 2.

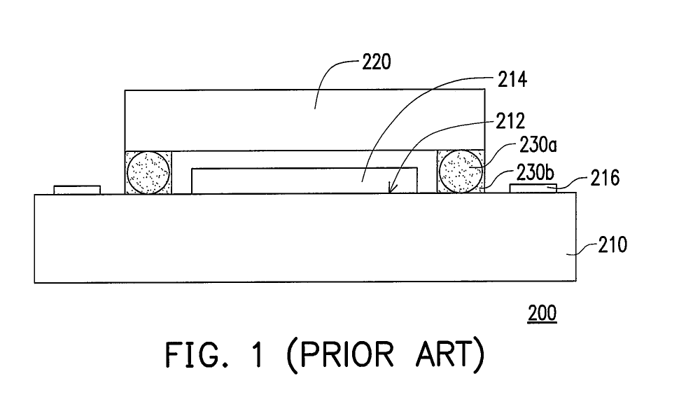

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

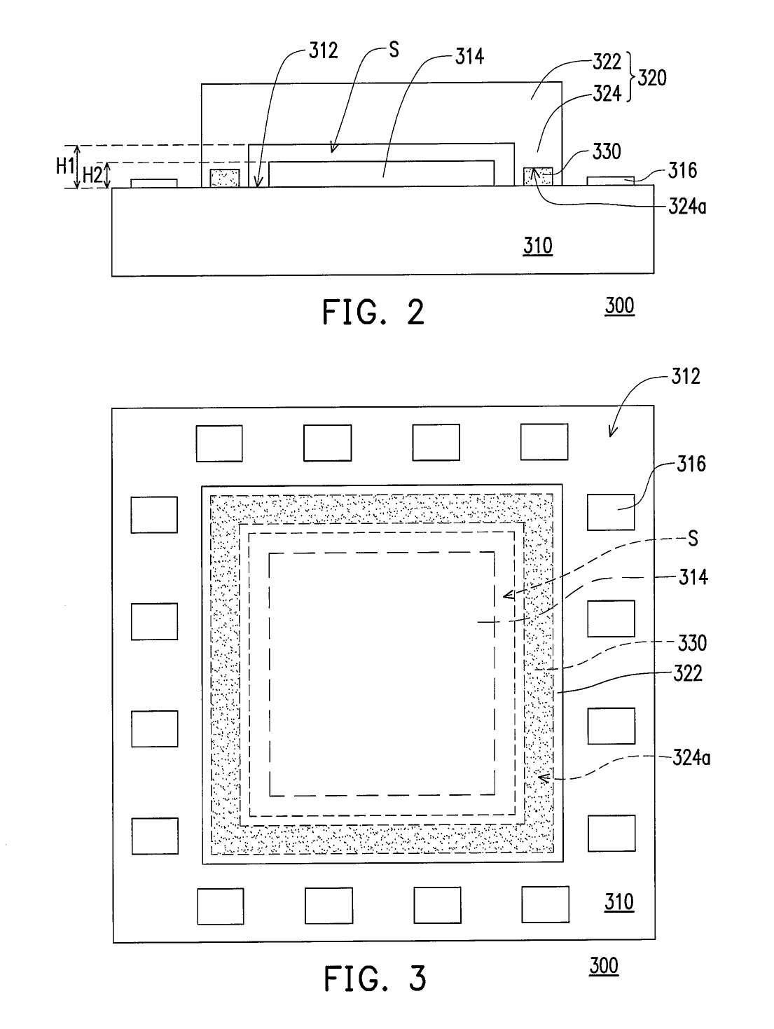

FIG. 2 is a schematic cross-sectional view of a chip package structure according to one preferred embodiment of the present invention. FIG. 3 is a top view of the chip package structure shown in FIG. 2. The chip package structure 300 as shown in FIGS. 2 and 3 comprises a chip 310, a package cover panel 320 and an adhesion layer 330. The chip 310 has an active surface 312. An image-sensing device 314 is disposed on the active surface 312 and a plurality of contact pads 316 is disposed around the image-sensing device 324. In one embodiment, the image-sensing device 314 includes a contact image sensor or a complementary metal-oxide-semiconductor (CMOS) image sensor for receiving an external light signal, for example. Through the chip 310, the light signal is converted into electric signal for further processing. The image-sensing device 314 is electrically connected to the surrounding contact pads 316 through metallic interconnecting wires (not shown), for example.

The package cover panel 320 is disposed above the active surface 312. Furthermore, the package cover panel 320 comprises a substrate 332 and a supporting part 324 disposed on the substrate 322. As shown in FIG. 2, the supporting part 324 defines a cavity S on the substrate 322 and the supporting part 324 is in contact with the active surface 312 so that the image-sensing device 314 on the active surface 312 is disposed within the cavity S. The adhesion layer 330 is disposed between the supporting part 324 and the active surface 312. Therefore, the image-sensing device 314 on the chip 310 will be covered by the package cover panel 320 and isolated from the outside world.

In particular, as shown in FIG. 2, the supporting part 324 of the package cover panel 320 in the present invention has a height H1 greater than the height H2 of the image-sensing device 314. Preferably, the height H1 of the supporting part 324 is set between 15 μm to 50 μm. In another preferred embodiment, the top end of the supporting part 324 has a groove 324a such that the adhesion layer 330 is disposed inside the groove 324a. In addition, the package cover panel 320 is fabricated using glass or polymethyl methacrylate (PMMA), for example. The adhesion layer 330 is fabricated using an ultra-violet adhesion material, for example.

It should be noted that the package cover panel 320 on the chip 310 is supported through the supporting part 324 of the package cover panel 320. Therefore, there is no particular limitation to the distance separating the package cover panel 320 from the chip 310. In other words, the height level of the supporting part 324 can be set to whatever level demanded. When the distance separating the package cover panel 320 and the chip 310 exceeds a certain limit, any micro-particle attached to the outer surface of the package cover panel 320 will not produce an image due to defocusing. Hence, the optical properties of the image-sensing device 314 on the chip 310 can hardly be affected by micro-particles.

Thereafter, a chip-on-board (COB) method or a chip-on-flex (COF) method is applied to connect electrically the contact pads 316 on the chip package structure 300 with the next stage of electronic device (not shown in FIG. 2).

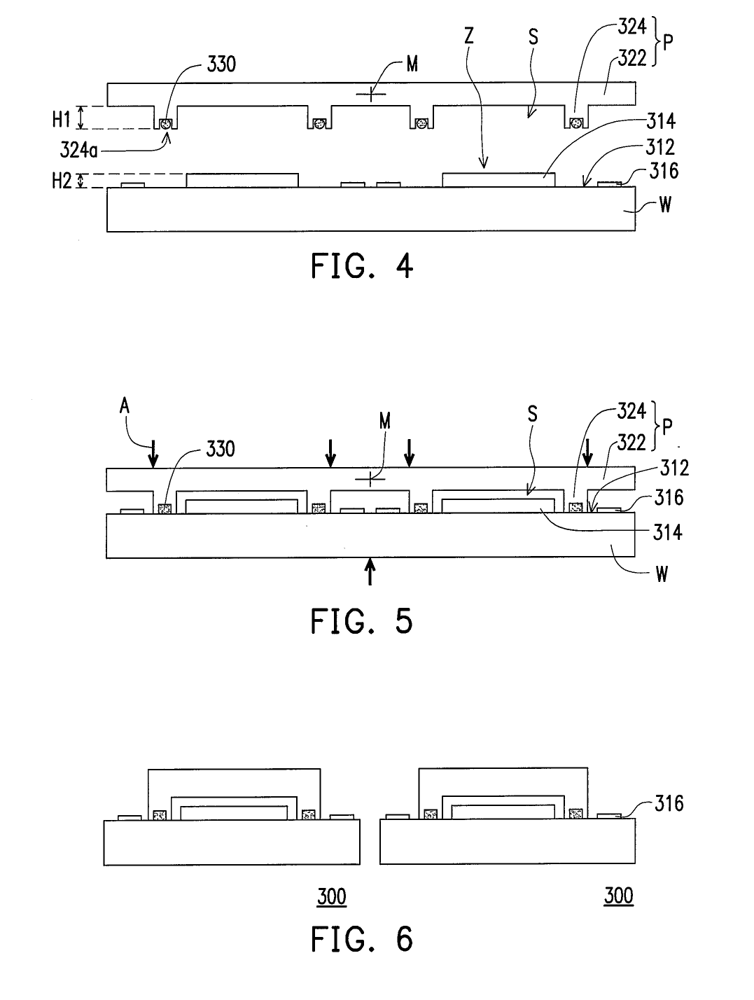

In the following, a method of fabricating the chip package structure 300 is explained. FIGS. 4 to 6 are schematic cross-sectional views showing the steps for forming the chip package structure shown in FIG. 2. First, as shown in FIG. 3, a wafer W having an active surface 312 is provided. The active surface 312 has a plurality image-sensing devices 314 formed thereon. The image-sensing devices 314 are within a plurality of device zones Z of the wafer W. Furthermore, a plurality of contact pads 316 is disposed around various image-sensing devices 314.

Then, a package cover panel P is provided. The package cover panel P comprises a substrate 322 and a supporting part 324 disposed on the substrate 322. The supporting part 324 defines a plurality of cavities S on the substrate 322. More specifically, the location and number of cavities S on the substrate 322 defined by the supporting part 324 depends on the location and number of device zones Z on the wafer W. Hence, when the wafer W and the package cover panel P are joined together in a subsequent process, the cavities S on the package cover panel P will exactly cover all the image-sensing devices 314 on the wafer W.

If the package cover panel P is fabricated using glass, photolithographic and etching processes can be used to form the package cover panel P. In other words, the method of forming the package cover panel P includes coating a layer of photoresist material globally over the surface of a large piece of glass. Then, an exposure and development process is performed to form a patterned photoresist layer. Thereafter, using the patterned photoresist layer as an etching mask, the glass panel is etched to form the package cover panel P. However, if the package cover panel P is fabricated using polymethyl methacrylate (PMMA), either the photolithographic and etching process or a molding process can be used. In the molding process, a large PMMA panel is compressed using a molding tool to produce the package cover panel P shown in FIG. 4.

As shown in FIG. 4, the support part 324 of the package cover panel P formed using the aforementioned process has a height H1 greater than the height H2 of the image-sensing devices 314 on the wafer W, for example. Preferably, the height H1 of the supporting part 324 is set between 15 μm to 50 μm. In one embodiment, the foregoing process of fabricating the package cover panel P may includes forming at least an alignment mark M on the package cover panel P. It should be noted that the thickness of the substrate 322 in corresponding position above the contact pads 316 might be trimmed down a bit to facilitate subsequent cutting operation (see the description below).

As shown in FIGS. 4 and 5, an adhesion layer 330 is formed between the supporting part 324 and the active surface 312 of the wafer W so that the package cover panel P and the active surface 312 of the wafer W are joined together. Furthermore, each image-sensing device 314 on the wafer W is disposed inside one of the cavities S. In the present embodiment (shown in FIG. 4), the adhesion layer 330 is coated within the groove 324a. However, the adhesion layer 330 can be pre-formed on the active surface 312 in a position that corresponds to the groove 324a. Furthermore, the foregoing step of joining the package cover panel P with the active surface 312 of the wafer W may include aligning using the alignment mark M so that each image-sensing device 314 is accurately disposed inside each cavity S.

Finally, as shown in FIGS. 5 and 6, the package cover panel P and the wafer W are independently dissected to form a plurality of independent chip package structures 300. In the present embodiment, the cutting is applied at the locations and orientations indicated by the arrowhead A in FIG. 5. Furthermore, the package cover panel P is cut using a laser or a diamond-tooled cutter method while the wafer W is normally cut using a diamond-tooled cutter. In addition, the timing of the cutting operation is also quite flexible. The package cover panel P can be cut before or after the wafer W or both the package cover panel P and the wafer W can be cut simultaneously. Moreover, in the process of cutting the package cover panel P, a portion of the substrate above the contact pads 316 will also be removed to expose the contact pads 316.

In summary, the major advantages of the chip package structure in the present invention at least includes:

1. A package cover panel is directly used to package the chip before cutting up the wafer. Hence, outside micro-particles can hardly deposit on the chip so that the process yield of the chip package structure is increased. Moreover, the manufacturing cost of the chip package structure can be lowered.

2. Because both the support part of the package-cover panel and the substrate are fabricated using a transparent material, a chip package structure using the package cover panel can have a higher optical transmissivity than a conventional chip package structure.

3. The distance separating the chip and the package cover panel can be set according to the actual requirements by adjusting the height of the support part. Furthermore, when the height of the supporting part exceeds a definite level, micro-particles attached to the outer surface of the package cover panel will not be able to form an image due to the defocusing effect at a large distance. Hence, the optical properties of the image-sensing device will be unaffected by micro-particles.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A package cover panel for packaging a wafer, wherein the wafer has a plurality of device regions, the package cover panel comprising:
a substrate; and
a supporting part disposed on the substrate, wherein the support part defines a plurality of cavities on the substrate such that each cavity corresponds with a device region on the wafer.

2. The package cover panel of claim 1, wherein the supporting part has a height between about 15 μm to 50 μm.

3. The package cover panel of claim 1, wherein the top end of the supporting part has a groove.

4. The package cover panel of claim 3, wherein the panel further comprises an adhesion layer located inside the groove.

5. The package cover panel of claim 1, wherein the panel further includes an alignment mark disposed on the substrate.

6. The package cover panel of claim 1, wherein the material constituting the package cover panel includes glass or polymethyl methacrylate (PMMA).

7. A chip package structure, comprising:
a chip having an active surface, wherein the active surface has an image-sensing device with a plurality of contact pads surrounding the image-sensing device;
a package cover panel disposed above the active surface, wherein the package cover panel comprises a substrate and a supporting part disposed on the substrate such that the supporting part defines a cavity on the substrate and the support part is in contact with the active surface of the chip so that the image-sensing device on the active surface is disposed inside the cavity; and
an adhesion layer disposed between the supporting part and the active surface.

8. The chip package structure of claim 7, wherein the supporting part has a height greater than the image-sensing device.

9. The chip package structure of claim 7, wherein the supporting part has a height between about 15 μm to 50 μm.

10. The chip package structure of claim 7, wherein the top end of the supporting part has a groove and the adhesion layer is disposed inside the groove.

11. The chip package structure of claim 7, wherein the material constituting the package cover panel includes glass or polymethyl methacrylate (PMMA).

12. A method of fabricating a chip package structure, comprising the steps of:
providing a wafer having an active surface, wherein the active surface has a plurality of image-sensing device disposed thereon and each image-sensing device is surrounded by a plurality of contact pads;
providing a package cover panel having a substrate and a supporting part disposed on the substrate, wherein the supporting part defines a plurality of cavities on the substrate;
forming an adhesion layer between the supporting part and the active surface of the wafer and joining the package cover panel with the active surface of the wafer, wherein the each image-sensing device on the wafer is disposed within a corresponding cavity; and
dissecting the package cover panel and the wafer separately to form a plurality of chip package structures.

13. The method of claim 12, wherein the step of forming the package cover panel includes performing a photolithographic and etching process or performing a molding process.

14. The method of claim 12, wherein the supporting part has a height greater than the image-sensing device on the wafer.

15. The method of claim 12, wherein the supporting part has a height between about 15 μm to 50 μm.

16. The method of claim 12, wherein the step of fabricating the package cover panel further includes forming a groove at the top end of the supporting part.

17. The method of claim 16, wherein the adhesion layer is coated within the groove.

18. The method of claim 12, wherein the step of fabricating the package cover panel further includes forming at least an alignment mark on the package cover panel.

19. The method of claim 18, wherein the step of joining the package cover panel with the active surface of the wafer further includes using the alignment mark to perform the alignment.

20. The method of claim 12, wherein the material constituting the package cover panel includes glass or polymethyl methacrylate (PMMA).
